(19) United States
(12) Patent Application Publication
(10) Pub. No.: US 2013/0342976 A1
(43) Pub. Date: Dec. 26, 2013

(54) SUPPORT MECHANISM AND ELECTRONIC DEVICE USING SAME

(71) Applicant: FIH (HONG KONG) LIMITED, Kowloon (HK)

(72) Inventor: Huan-Chang CHUNG, Shindian (TW)

(73) Assignee: FIH (Hong Kong) Limited, Kowloon (HK)

(21) Appl. No.: 13/728,092

(22) Filed: Dec. 27, 2012

(30) Foreign Application Priority Data
Jun. 25, 2012 (CN) 2012102100166

(51) Int. Cl. H05K 5/02

(52) U.S. Cl. CPC H05K 5/0234; H05K 5/0204
USPC 361/679.01; 248/688

(57) ABSTRACT

A support mechanism includes a housing, a securing portion and a stylus. The housing defines a groove. The securing portion includes a plurality of arcuate portions and a slot defined among the plurality of arcuate portions, the slot communicating with the groove. The stylus includes a stylus tip, a stylus body and a spherical portion, the stylus tip positioned at a first end of the stylus body, and the spherical portion positioned at a second end of the stylus body, the stylus tip and the stylus body received in the groove, and the spherical portion received in the slot. When the spherical portion is rotated in the slot to a support position, the stylus is able to support the housing.

### BACKGROUND

1. Technical Field

The exemplary disclosure relates to support mechanisms, particularly to support mechanisms used in electronic devices.

2. Description of Related Art

Some portable electronic products have a bracket on the back of its casing. Thus, when the bracket is opened, the portable electronic product becomes supported and able to sit on the desk or other supporting surface to make it more comfortable for the users to view the displays.

However, typical brackets of the existing portable electronic products have a complicated structure and are difficult to manufacture and use.

Therefore, there is room for improvement within the art.

### BRIEF DESCRIPTION OF THE DRAWINGS

Many aspects of the exemplary support mechanism and electronic device using the support mechanism can be better understood with reference to the following drawings. These drawings are not necessarily drawn to scale, the emphasis instead being placed upon clearly illustrating the principles of the present support mechanism and electronic device. Moreover, in the drawings like reference numerals designate corresponding parts throughout the several views. Wherever possible, the same reference numbers are used throughout the drawings to refer to the same or like elements of an embodiment.

FIG. 1 is a schematic view of an electronic device with a support mechanism in a closed position according to an exemplary embodiment.

FIG. 2 is an exploded view of the support mechanism shown in FIG. 1.

FIG. 3 is similar to the FIG. 2, showing the support mechanism in use.

### DETAILED DESCRIPTION

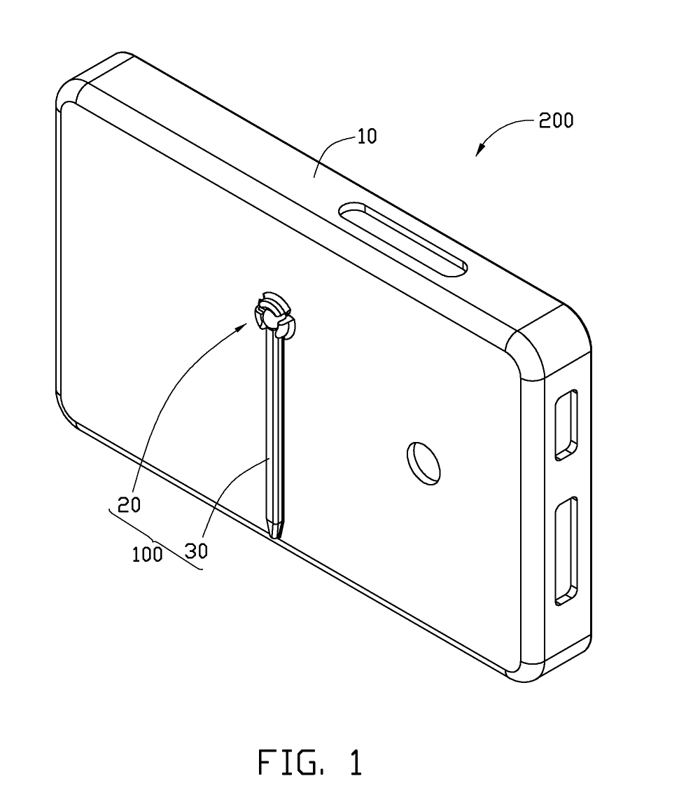

An embodiment of an electronic device 200 incorporating a support mechanism 100 is shown in FIGS. 1 to 3. FIG. 1 illustrates the support mechanism 100 in an assembled state. The electronic device 200 has a housing 10. The support mechanism 100 comprises a securing portion 20 and a stylus 30.

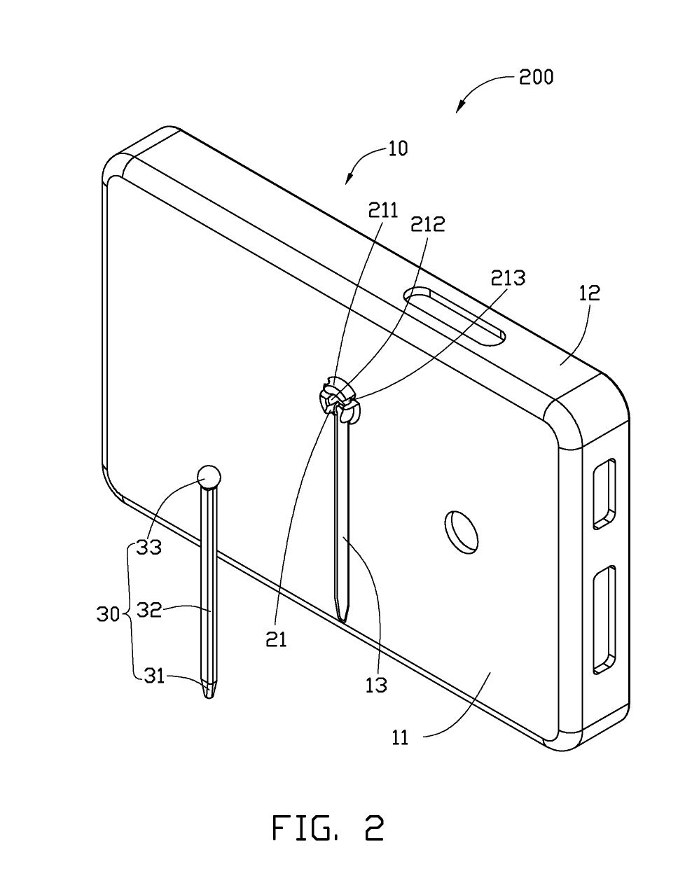

FIG. 2 shows an exploded view of the support mechanism 100. The housing 10 comprises a back plate 11 and a peripheral wall 12. A bar-shaped groove 13 is defined in the back plate 11 for receiving the stylus 30.

The securing portion 20 is located at one end of the groove 13. In this exemplary embodiment, the securing portion 20 is integrally formed with the housing 10. The securing portion 20 comprises a plurality of arcuate portions 211 and a circular slot 21 is defined among the arcuate portions 211. The circular slot 21 communicates with the groove 13. Each arcuate portion 211 has an inside surface 212. The inside surfaces 212 constitute a partial spherical surface configured for engaging with one end of the stylus 30. In this exemplary embodiment, there are three arcuate portions 211. A cutout 213 is defined between each two arcuate portions 211. The cutout 213 can allow the arcuate portions 211 to be deformed when one end of the stylus 30 is received in the slot 21.

The stylus 30 can function to touch a touch screen of the electronic device 200. The stylus 30 comprises a stylus tip 31, a stylus body 32 and a spherical portion 33. The stylus tip 31 is positioned at a first end of the stylus body 32, and the spherical portion 33 is positioned at a second end of the stylus body 32. A diameter of the spherical portion 33 is slightly larger than that of the spherical surface. The spherical portion 33 may be received in the slot 21, and rotatably engages with the partial spherical surface of the slot 21.

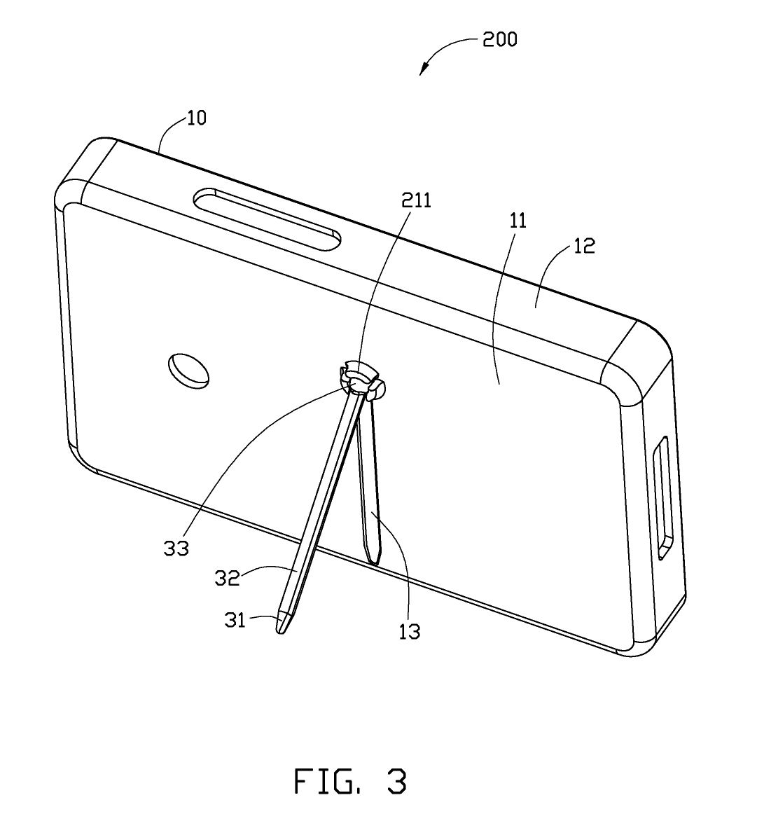

FIGS. 1 and 3 show that when the stylus 30 is not used, the stylus tip 31 and the stylus body 32 is received in the groove 13, and the spherical portion 33 is pressed into the slot 21. The arcuate portions 211 are deformedly stretched to allow the spherical portion 33 to be latched in the slot 21. When the stylus 30 is used for supporting the electronic device 200, the stylus tip 31 and the stylus body 32 are pulled out of the groove 13, and the spherical portion 33 is rotated in the slot 21 allowing the stylus 30 to support the electronic device 200. The spherical portion 33 can provide any angle of support between the stylus 30 and the housing 10. When the support mechanism 100 is in a closed state, like shown FIG. 1, the stylus 30 is received in the groove 13 and is flush with the back plate 11 of the housing 10 making the housing 10 convenient to carry. When the stylus 30 is used for supporting the housing 10, a user can adjust the spherical portion 33 to adjust the angle of the stylus relative to the housing until the housing 10 is at a comfortable viewing angle, such as shown in FIG. 3.

Even though numerous characteristics and advantages of the present embodiments have been set forth in the foregoing description, together with details of structures and functions of various embodiments, the disclosure is illustrative only, and changes may be made in detail, especially in matters of shape, size, and arrangement of parts within the principles of the present invention to the full extent indicated by the broad general meaning of the terms in which the appended claims are expressed.

What is claimed is:

1. A support mechanism, comprising:
a housing defining a groove;
a securing portion comprising a plurality of arcuate portions and a slot defined among the plurality of arcuate portions, the slot communicating with the groove; and
a stylus comprising a stylus tip, a stylus body, and a spherical portion; the stylus tip positioned at a first end of the stylus body, and the spherical portion positioned at a second end of the stylus body; the stylus tip and the stylus body received in the groove;
and the spherical portion received in the slot;
wherein when the spherical portion is rotated in the slot to a support position, the stylus is able to support the housing.

2. The support mechanism of claim 1, wherein each arcuate portion has an inside surface, the inside surfaces constitute a partial spherical surface engaging with the spherical portion.

3. The support mechanism of claim 1, wherein there are three arcuate portions, and a cutout is defined between each two arcuate portions.

4. The support mechanism of claim 3, wherein a diameter of the spherical portion is slightly larger than that of the partial spherical surface.

5. An electronic device, comprising:
a housing defining a groove;
a securing portion defining a slot communicating with the groove; and
a stylus comprising a stylus tip, a stylus body and a spherical portion, the stylus tip positioned at a first end of the stylus body, and the spherical portion positioned at a second end of the stylus body;
wherein when in a first state, the stylus tip and the stylus body are received in the groove, and the spherical portion are received in the slot; and when in a second state, the spherical portion is rotated in the slot to a support position allowing the stylus to support the housing.

6. The electronic device of claim 5, wherein a plurality of arcuate portions surround the slot, each of the plurality of arcuate portions has an inside surface, the inside surfaces constitute a partial spherical surface engaging with the spherical portion.

7. The electronic device of claim 6, wherein a diameter of the spherical portion is slightly larger than that of the partial spherical surface.
